(19) United States
(12) Patent Application Publication
(10) Pub. No.: US 2025/0101581 A1
(43) Pub. Date: Mar. 27, 2025

(54) APPARATUS AND METHODS FOR PERFORMING AN IN-SITU ETCH OF REACTION CHAMBERS WITH FLUORINE-BASED RADICALS

(71) Applicant: ASM IP Holding B.V., Almere (NL)

(72) Inventors: Amit Mishra, Tempe, AZ (US); Bhushan Zope, Phoenix, AZ (US); Shankar Swaminathan, Phoenix, AZ (US); Theodorus G.M. Oosterlaken, Oudewater (NL)

(21) Appl. No.: 18/973,788

(22) Filed: Dec. 9, 2024

Related U.S. Application Data
(63) Continuation of application No. 17/307,007, filed on May 4, 2021, now Pat. No. 12,203,166.
(60) Provisional application No. 63/021,514, filed on May 7, 2020.

(51) Int. Cl. C23C 16/44; C23C 16/06; C23C 16/455; C23C 16/52; H01J 37/32

(52) U.S. Cl. CPC C23C 16/4408; C23C 16/06; C23C 16/4405; C23C 16/45536; C23C 16/52; H01J 37/32862

(57) ABSTRACT

An apparatus and method for cleaning or etching a molybdenum film or a molybdenum nitride film from an interior of a reaction chamber in a reaction system are disclosed. A remote plasma unit is utilized to activate a halide precursor mixed with an inert gas source to form a radical gas. The radical gas reacts with the molybdenum film or the molybdenum nitride film to form a by-product that is removed from the interior of the reaction chamber by a purge gas.

### CROSS-REFERENCE TO RELATED APPLICATIONS

This application is a continuation of, and claims priority to and the benefit of, U.S. patent application Ser. No. 17/307,007 filed May 4, 2021 and entitled “APPARATUS AND METHODS FOR PERFORMING AN IN-SITU ETCH OF REACTION CHAMBERS WITH FLUORINE-BASED RADICALS,” which claims priority to and the benefit of, U.S. Provisional Patent Application No. 63/021,514, filed May 7, 2020 and entitled “APPARATUS AND METHODS FOR PERFORMING AN IN-SITU ETCH OF REACTION CHAMBERS WITH FLUORINE-BASED RADICALS,” the disclosures of which are hereby incorporated by reference herein.

### FIELD OF INVENTION

The present disclosure relates generally to an apparatus and methods for cleaning a reaction chamber after a film has been deposited on interior walls of the reaction chamber. The present disclosure more specifically relates to using halogen-based radicals for performing the cleaning or an in-situ etch of the deposited film.

### BACKGROUND OF THE DISCLOSURE

Semiconductor fabrication processes for forming semiconductor device structures, such as, for example, transistors, memory elements, and integrated circuits, are wide ranging and may include deposition processes. The deposition processes may result in films such as molybdenum or molybdenum nitride deposited on the substrates.

During the deposition processes, the molybdenum or molybdenum nitride films may also accumulate on interior walls of the reaction chamber. If too much of these films accumulate on the walls, adverse effects may occur such as drifting process performance due to temperature irregularities caused by the accumulated films. In addition, the accumulated films may cause particle issues on processed substrates.

Traditional preventative reaction chamber maintenance may need periodic replacement of parts for the reaction chamber. This may result in significant down time (on the order of 1 week or more), causing a high loss in production.

Accordingly, apparatuses and methods are desired to clean deposited molybdenum or molybdenum nitride films from walls of reaction chambers that do not require a significant down time in production.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In at least one embodiment of the invention, a method for cleaning an interior wall of a reaction chamber is disclosed. The method comprises: providing a reaction chamber in which a molybdenum film is deposited on an interior wall of the reaction chamber; igniting a remote plasma unit by flowing an inert gas into the remote plasma unit; flowing a halide precursor into the remote plasma unit to form a radical gas; flowing the radical gas from the remote plasma unit into the reaction chamber, wherein the radical gas reacts with the molybdenum film; and flowing a purge gas to remove a by-product of the reaction of the radical gas with the molybdenum film from the reaction chamber; wherein the molybdenum film comprises at least one of: molybdenum; or molybdenum nitride.

In at least one embodiment of the invention, a reaction system for depositing a semiconductor film is disclosed. The reaction system comprises: a reaction chamber configured to hold a substrate to be processed, the reaction chamber having a deposited film on an interior of the reaction chamber, wherein the deposited film comprises at least one of: molybdenum or molybdenum nitride; a remote plasma unit; a halide precursor source configured to provide a halide gas to the remote plasma unit; an inert gas source configured to provide an inert gas to the remote plasma unit; a first reactant precursor source configured to provide a first reactant precursor to the reaction chamber, wherein the first reactant precursor does not enter the remote plasma unit; and a second reactant precursor or purge gas source configured to provide a second reactant precursor or a purge gas to the reaction chamber; wherein the remote plasma unit is configured to activate a mixture of the halide gas and the inert gas to form a radical gas that flows to the reaction chamber; and wherein the radical gas reacts with the deposited film to remove the deposited film from the reaction chamber.

In at least one embodiment of the invention, a batch reaction system for depositing a semiconductor film is disclosed. The reaction system comprises: a reaction tube configured to hold a substrate boat to be processed, the reaction tube having a deposited film on an interior of the reaction tube, wherein the deposited film comprises at least one of: molybdenum or molybdenum nitride; an in situ radical generator; a halide precursor source configured to provide a halide gas to the reaction tube; an inert gas source configured to provide an inert gas to the reaction tube; an oxygen gas source configured to provide an oxygen gas to the reaction tube; a first reactant precursor source configured to provide a first reactant precursor to the reaction tube; and a second reactant precursor source configured to provide a second reactant precursor to the reaction chamber; wherein the in situ radical generator is configured to activate the halide gas to form a radical gas in the reaction tube; and wherein the radical gas reacts with the deposited film to remove the deposited film from the reaction tube.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIG. 1 illustrates a non-limiting exemplary process flow, demonstrating a method for cleaning a molybdenum or molybdenum nitride film from interior walls of a reaction chamber according to the embodiments of the disclosure.

FIG. 2 illustrates a cross-sectional schematic diagram of a film deposition system according to the embodiments of the disclosure.

FIG. 3 illustrates a batch reactor system in accordance with at least one embodiment of the disclosure.

The illustrations presented herein are not meant to be actual views of any particular material, structure, or device, but are merely idealized representations that are used to describe embodiments of the disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials that may be used, or upon which, a device, a circuit, or a film may be formed.

As used herein, the term “cyclical chemical vapor deposition” may refer to any process wherein a substrate is sequentially exposed to one or more volatile precursors, which react and/or decompose on a substrate to produce a desired deposition.

As used herein, the term “atomic layer deposition” (ALD) may refer to a vapor deposition process in which deposition cycles, preferably a plurality of consecutive deposition cycles, are conducted in a reaction chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition”, “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “film” and “thin film” may refer to any continuous or non-continuous structures and material formed by the methods disclosed herein. For example, “film” and “thin film” could include 2D materials, nanolaminates, nanorods, nanotubes, or nanoparticles, or even partial or full molecular layers, or partial or full atomic layers or clusters of atoms and/or molecules. “Film” and “thin film” may comprise material or a layer with pinholes, but still be at least partially continuous.

A number of example materials are given throughout the embodiments of the current disclosure, it should be noted that the chemical formulas given for each of the materials should not be construed as limiting and that the non-limiting example materials given should not be limited by a given example stoichiometry.

The present disclosure includes an apparatus and method for cleaning a reaction system that performs a molybdenum film deposition process. Molybdenum thin films may be utilized in a number of applications, such as, for example, low electrical resistivity gap-fill, liner layers for 3D-NAND, DRAM word-line features, metal gate, DRAM top electrode, memory, or as an interconnect material in CMOS logic applications.

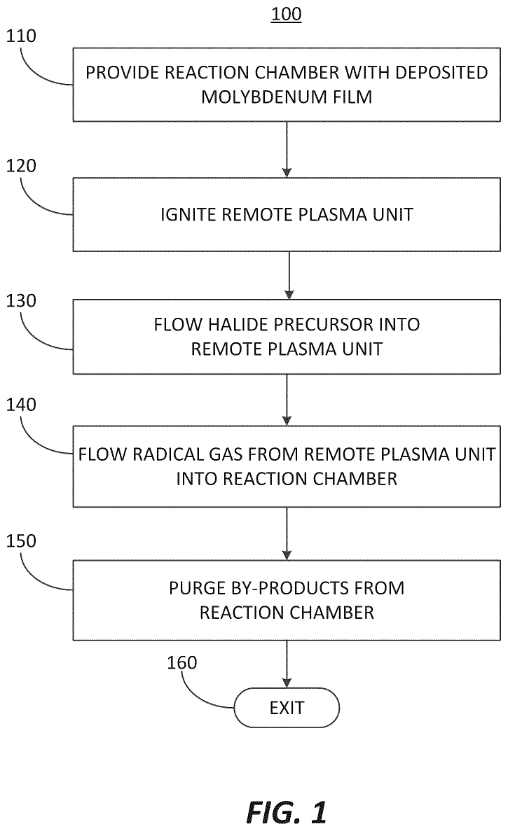

FIG. 1 illustrates a method 100 for cleaning a reaction system in accordance with at least one embodiment of the invention. The method 100 comprises: (1) providing a reaction chamber that has a deposited molybdenum film 110; (2) igniting a remote plasma unit 120; (3) flowing a halide precursor into the remote plasma unit 130; (4) flowing a radical gas formed in the remote plasma unit into the reaction chamber 140; and (5) purging by-products from the reaction chamber 150. The process then may exit in a step 160, whereby further processing steps occur, such as additional film deposition processes, cleaning processes, or annealing processes.

The deposited molybdenum film in step 110 may comprise molybdenum or molybdenum nitride. The igniting step 120 may comprise flowing an inert gas in to the remote plasma unit. The inert gas may comprise at least one of: argon; xenon; or another inert gas. The remote plasma unit employed may include one manufactured by MKS Instruments, Inc. or Lightwind Corporation.

Once the plasma is ignited, the flowing the halide precursor into the remote plasma unit step 130 occurs. The halide precursor may comprise at least one of: nitrogen trifluoride (NF₃); sulfur hexafluoride ((SF₆); carbon tetrafluoride (CF₄); fluoroform (CHF₃); octafluorocyclobutane (C₄F₈); chlorine trifluoride (ClF₃); fluorine (F₂); or a combination of the above. This causes a formation of radical gases, comprising fluorine radicals, for example.

The formed radical gas is then flowed from the remote plasma unit into the reaction chamber in step 140. The reaction chamber may be maintained at temperatures ranging between 300° C. and 550° C., between 350° C. and 500° C., or between 400° C. and 450° C. Temperatures that are too high may result in an excessively reactive radical gas, causing removal of more than the molybdenum or molybdenum nitride films than desired.

A flow rate of the formed radical gas may affect a rate at which the removal of the molybdenum or molybdenum nitride film occurs. The flow rate may be affected by a flow rate of the inert gas provided to the remote plasma unit. A higher flow rate of the formed radical gas may allow for quicker removal of the film. This may reduce the downtime of the reaction chamber for maintenance. A higher flow rate of the formed radical gas may range between 1500 and 3000 sccm, between 2000 and 3000 sccm, or between 2500 to 3000 sccm.

However, there may be situations where a lower flow rate of the formed radical gas is desired. The lower flow rate may be desired for areas of the reaction chamber that are more difficult for the radical gas to reach. A lower flow rate will increase a residence time of the formed radical gas, allowing it to get to the harder-to-reach areas, such as the corners of the reaction chamber. This way, a thorough cleaning of the reaction chamber may be achievable. A lower flow rate of the formed radical gas may range between 50 to 500 sccm, between 100 to 300 sccm, or between 100 to 200 sccm.

The method 100 also comprises a step 150 for purging by-products from the reaction chamber. The radical gas reacts with the deposited molybdenum films and may form a gaseous by-product. These by-products are then removed from the reaction chamber by purging an inert gas. The inert gas may comprise at least one of: argon; xenon; nitrogen; or helium.

In at least one embodiment of the invention, fluorine radicals may be utilized to remove a molybdenum film deposited on an inner wall of the reaction chamber. The fluorine radicals are formed according to a first reaction in the remote plasma unit during step 130, utilizing nitrogen trifluoride (NF₃) as an exemplary halide precursor:

NF₃→F*+NF₂+NF

The fluorine radicals then react with the molybdenum film in this manner to form the by-products during step 140:

F*+Mo→MoF_{6(g)}

These by-products are then removed from the reaction chamber with the inert gas in step 150.

Reactors or reaction chambers suitable for performing the embodiments of the disclosure may include ALD reactors, as well as CVD reactors, configured to provide the precursors. According to some embodiments, a showerhead reactor may be used. According to some embodiments, single-wafer, cross-flow, batch, minibatch, or spatial ALD reactors may be used.

In some embodiments of the disclosure, a batch reactor may be used. In some embodiments, a vertical batch reactor may be used. In other embodiments, a batch reactor comprises a minibatch reactor configured to accommodate 10 or fewer wafers, 8 or fewer wafers, 6 or fewer wafers, 4 or fewer wafers, or 2 or fewer wafers.

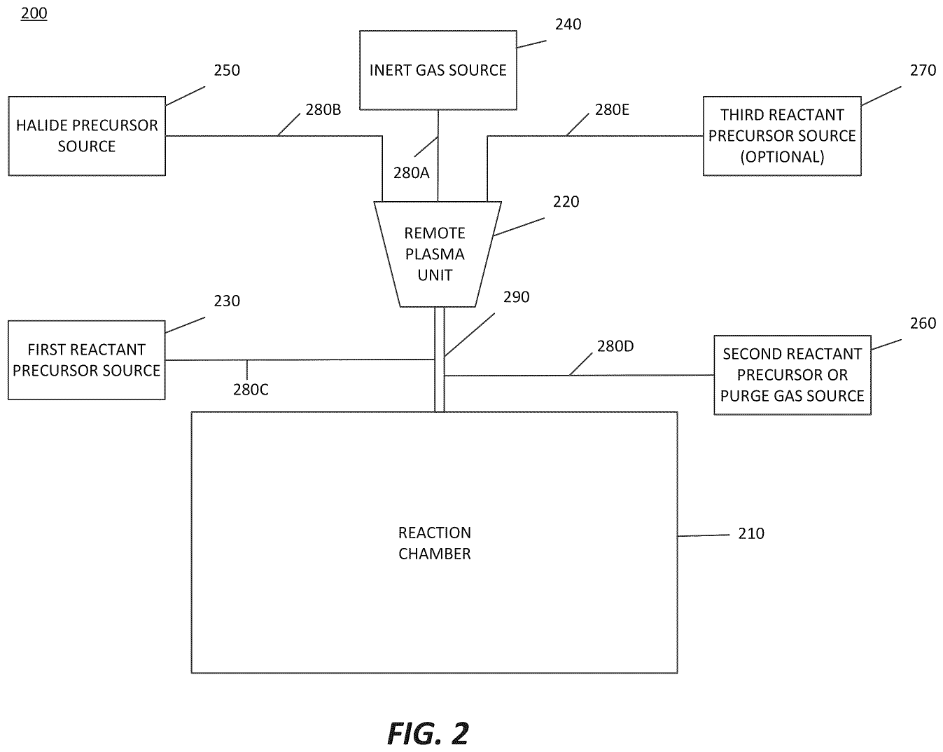

FIG. 2 illustrates a reaction system 200 in accordance with at least one embodiment of the invention. The reaction system 200 may comprise: a reaction chamber 210; a remote plasma unit 220; a first reactant precursor source 230; an inert gas source 240; a halide precursor source 250; a second reactant precursor or purge gas source 260; an optional third reactant precursor source 270; a series of gas lines 280A-280E; and a main gas line 290.

The reaction chamber 210 may have a shape and constitution depending on the type of reaction system 200 employed, whether it be a batch, single-wafer, or mini-batch tool, for example. The shape and constitution of the reaction chamber 210 may also depend on a process employed in the reaction system 200; for example, whether the process is an ALD or a CVD process.

The remote plasma unit 220 is ignited by an inert gas provided from the inert gas source 240 via the gas line 280A. The remote plasma unit 220 then activates a halide gas provided by the halide precursor source 250 via the gas line 280B. The halide gas from the halide precursor source 250 may comprise at least one of: nitrogen trifluoride (NF₃); sulfur hexafluoride (SF₆); carbon tetrafluoride (CF₄); fluoroform (CHF₃); octafluorocyclobutane (C₄F₈); chlorine trifluoride (ClF₃); fluorine (F₂); or a mixture of the above.

The activated halide gas and the inert gas form a radical gas that then travels to the reaction chamber 210 via the main gas line 290. The main gas line 290 may also comprise an injector system if the reaction system 200 is a batch or a mini-batch system. The main gas line 290 may also comprise a manifold, a showerhead, or an injection flange for a single-wafer system.

The reaction system 200 may also comprise a first reactant precursor source 230 that provides a first reactant precursor to the reaction chamber 210 via the gas line 280C in order to deposit a molybdenum film or a molybdenum nitride film. The first reactant precursor may comprise at least one of: a molybdenum halide precursor, such as a molybdenum chloride precursor, a molybdenum iodide precursor, or a molybdenum bromide precursor; or a molybdenum chalcogenide, such as a molybdenum oxychloride, a molybdenum oxyiodide, a molybdenum (IV) dichloride dioxide (MoO₂Cl₂) precursor, or a molybdenum oxybromide.

The reaction system 200 may also comprise a second reactant precursor or a purge gas source 260 that provides a reactant precursor or a purge gas via the gas line 280D. If the gas source 260 provides a purge gas, the purge gas may be utilized to remove by-products of the reaction between the deposited molybdenum or molybdenum nitride film and the radical gas as above described in step 150 of the method 100. If the gas source 260 provides a second reactant precursor, the second reactant precursor may react with the first reactant precursor from the first reactant precursor source 230 to deposit the molybdenum film or the molybdenum nitride film.

The reaction system 200 may also comprise an optional third reactant precursor source 270 that provides an optional third reactant to the remote plasma unit 220 via the gas line 280E. The optional third reactant is then activated and flows to the reaction chamber 210, where it may react with the first reactant precursor or the second reactant precursor to deposit the molybdenum film or the molybdenum nitride film. The optional third reactant precursor source 270 may be employed where an activated precursor is necessary, such as in low temperature deposition processes.

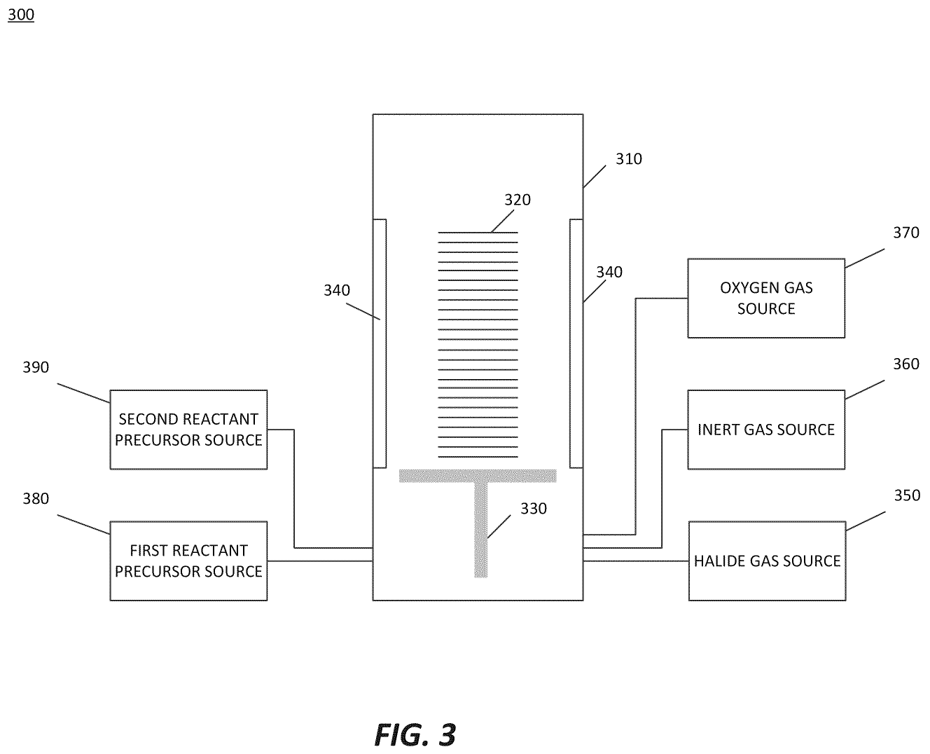

In at least one embodiment of the disclosures, a batch reactor system may be cleaned of a molybdenum or molybdenum nitride film deposited inside a reaction tube. FIG. 3 illustrates a batch reactor system 300 in accordance with at least one embodiment of the invention. The batch reactor system 300 comprises: a reaction tube 310; a boat of wafers 320; a wafer boat holder 330; an in situ radical generator 340; a halide gas source 350; an inert gas source 360; an oxygen gas source 370; a first reactant precursor source 380; and a second reactant precursor source 390.

The reaction tube 310 may comprise quartz and defines a reaction space in which a molybdenum film or a molybdenum nitride film is deposited on wafers disposed within the boat 320. The wafer boat holder 330 holds the wafer boat 320 and moves wafers into and out of the reaction tube 310. During the cleaning process, it may be preferable that the wafer boat 320 be outside of the reaction tube 310.

The in situ radical generator 340 may comprise an in situ plasma generator, such as an inductively coupled plasma (ICP) generator or a capacitively coupled plasma (CCP) generator. Alternatively, the in situ radical generator 340 may be optional as chemistries of the halide gas source 350 may prove to be unstable and naturally form radicals; for example, a metallic surface within the batch reactor system 300 may cause formation of radicals should it get in contact with an unstable halide gas such as nitrogen trifluoride (NF₃) or chlorine trifluoride (ClF₃).

The halide gas source 350 may provide a halide gas to the reaction tube 310 via gas line and an injector structure. The halide gas may comprise at least one of: nitrogen trifluoride (NF₃); chlorine trifluoride (ClF₃); fluorine (F₂); chlorine (Cl₂); or combinations of the above. The halide gas may be used to etch a layer of metallic molybdenum or molybdenum nitride formed on the quartz of the reaction tube 310. The flow of the halide gas may range between 10 sccm and 700 sccm, between 50 sccm and 600, or between 100 and 300 sccm. The flow rate of the halide gas should be such that damage to an interior of the batch reactor system 300 is limited when the halide gas is heated. The temperature within the reaction tube 310 during the clean process may range between 300° C. and 750° C., between 350° C. and 700° C., or between 400° C. and 600° C. The pressure within the reaction tube 310 during the clean process may range between 0.1 and 10 Torr, between 0.5 and 5 Torr, or between 1 and 3 Torr.

The inert gas source 360 may provide an inert gas to the reaction tube 310 via a gas line and injector structure. The inert gas may comprise at least one of: argon; xenon; nitrogen; or helium. The inert gas may function to activate in situ plasma within the reaction tube 310, should the in situ radical generator 340 comprise an in situ plasma generator. The activated in situ plasma then converts the halide gas into a radical gas. The inert gas may also be used to purge out any by-products from the reaction of the radical gas with the deposited molybdenum or molybdenum nitride films on the reaction tube 310. This process may allow for a greater selectivity to etch or clean the molybdenum or molybdenum nitride deposited on quartz in comparison to molybdenum or molybdenum nitride deposited on other surfaces.

Once the clean or etch process is completed, an annealing process with oxygen gas from the oxygen gas source 370 may be used to passivate the quartz material. The oxygen gas may comprise at least one of: oxygen (O₂); water vapor (H₂O); or hydrogen peroxide (H₂O₂). By passivating the quartz of the reaction tube 310, this avoids a memory effect during further molybdenum or molybdenum nitride deposition.

The first reactant precursor source 380 and the second reactant precursor source 390 may provide a first reactant precursor and a second reactant precursor used to deposit a molybdenum or molybdenum nitride film onto the wafers disposed in the wafer boat 310. The first reactant precursor may comprise at least one of: a molybdenum halide precursor, such as a molybdenum chloride precursor, a molybdenum iodide precursor, or a molybdenum bromide precursor; or a molybdenum chalcogenide, such as a molybdenum oxychloride, a molybdenum oxyiodide, a molybdenum (IV) dichloride dioxide (MoO₂Cl₂) precursor, or a molybdenum oxybromide.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combination of the elements described, may become apparent to those skilled in the art from the description. Such modifications and embodiments are also intended to fall within the scope of the appended claims.

What is claimed is:

1. A method for cleaning an interior wall of a reaction chamber, the method comprising:
providing the reaction chamber in which a molybdenum-containing film is deposited on the interior wall of the reaction chamber;
forming a radical gas, wherein forming the radical gas comprises:
igniting a remote plasma unit by flowing an inert gas into the remote plasma unit, wherein the inert gas consists essentially of one or more of argon, helium, and nitrogen, and
flowing a halide precursor into the remote plasma unit; and
flowing a gas consisting essentially of the radical gas into the reaction chamber.

2. The method of claim 1, wherein the reaction chamber is integral to at least one of an atomic layer deposition (ALD) reaction system, a chemical vapor deposition (CVD) reaction system, a single-wafer deposition system, a batch wafer deposition system, a vertical furnace deposition system, a cross-flow deposition system, a minibatch deposition system, or a spatial ALD deposition system.

3. The method of claim 1, wherein the inert gas consists essentially of argon.

4. The method of claim 1, wherein the halide precursor comprises nitrogen trifluoride (NF₃), sulfur hexafluoride (SF₆), carbon tetrafluoride (CF₄), fluoroform (CHF₃), octafluorocyclobutane (C₄F₈), chlorine trifluoride (ClF₃), or fluorine (F₂).

5. The method of claim 1, further comprising flowing a purge gas to remove a by-product of the reaction of the radical gas with the molybdenum-containing film from the reaction chamber.

6. The method of claim 5, wherein the purge gas comprises nitrogen (N₂), helium, or argon.

7. The method of claim 1, further comprising flowing a first reactant from a first reactant precursor source to deposit the molybdenum-containing film.

8. The method of claim 7, wherein the first reactant comprises a molybdenum halide precursor, a molybdenum chalcogenide, or a molybdenum oxyhalide.

9. The method of claim 1, wherein the step of flowing the halide precursor is after the step of igniting the remote plasma unit.

10. The method of claim 1, wherein a temperature of the reaction chamber ranges between 300° C. and 550° C.

11. The method of claim 5, wherein the interior wall comprises a quartz surface.

12. The method of claim 11, further comprising passivating the quartz surface by flowing an oxygen-containing gas into the reaction chamber after the step of flowing the purge gas, wherein the oxygen-containing gas comprises oxygen (O₂), water vapor (H₂O), or hydrogen peroxide (H₂O₂).

13. The method of claim 10, wherein a pressure of the reaction chamber ranges between 1 and 3 Torr.

14. The method of claim 1, wherein the molybdenum-containing film comprises metallic molybdenum or molybdenum nitride.

15. The method of claim 1, wherein forming the radical gas consists essentially of:
igniting the remote plasma unit by flowing the inert gas into the remote plasma unit, and
flowing the halide precursor into the remote plasma unit.

16. The method of claim 1, wherein the radical gas reacts with the molybdenum-containing film.

17. A method for cleaning an interior wall of a reaction tube, the method comprising:
providing a reactor system in which a molybdenum-containing film is deposited on the interior wall of the reaction tube;
flowing a halide gas into the reaction tube; and
activating an in situ radical generator in the reaction tube to form a radical gas from the halide gas,
wherein the radical gas etches the molybdenum-containing film.

18. The method of claim 17, further comprising flowing an inert gas into the reaction tube before activating the in situ radical generator.

19. The method of claim 17, further comprising flowing an inert gas to remove a by-product of a reaction of the radical gas with the molybdenum-containing film from the reaction tube.

20. A method for cleaning an interior wall of a reaction tube, the method comprising:
providing a reactor system in which a molybdenum-containing film is deposited on a quartz surface of the interior wall of the reaction tube; and
flowing a halide gas into the reaction tube;
wherein the halide gas reacts with a metallic surface within the reactor system to form a radical gas, and
wherein the radical gas etches the molybdenum-containing film.
